(19) United States
(12) Patent Application Publication
(10) Pub. No.: US 2007/0125419 A1
(43) Pub. Date: Jun. 7, 2007

(54) Dye sensitized solar cells having blocking layers and methods of manufacturing the same

(76) Inventors: John Yupeng Gui, Niskayuna, NY (US); Venkatesan Manivannan, Rexford, NY (US); Aharon Yakimov, Niskayuna, NY (US); Kevin Janora, Schenectady, NY (US)

Correspondence Address: Patrick S. Yoder;FLETCHER YODER, P.O. Box 692289, Houston, TX, 77269-2289, US

(21) Appl. No.: 11/291,704

(22) Filed: Dec. 1, 2005

(51) Int. Cl. H01L 31/00

(52) U.S. Cl. 136/252

(57) ABSTRACT

A solar cell having at least one hole blocking layer and at least one electron blocking layer, and methods of fabricating such devices. Specifically, a hole blocking layer is disposed between a first electrode of the solar cell and the active layer. Further, an electron blocking layer is disposed between a second electrode and the active layer. The solar cell may be formed by fabricating an anode component and a cathode component and laminating the anode component and the cathode component together.

### BACKGROUND OF THE INVENTION

Photovoltaic systems are implemented to convert light energy into electricity for a variety of applications. Power production by photovoltaic systems may offer a number of advantages over conventional systems. These advantages may include, but are not limited to, low operating costs, high reliability, modularity, low fabrication costs, and environmental benefits. As can be appreciated, photovoltaic systems include a number of photovoltaic devices, commonly known as “solar cells,” so named for their ability to produce electricity from sunlight.

Conventional solar cells convert light into electricity by exploiting the photovoltaic effect that exists at semiconductor junctions. Accordingly, conventional solar cells generally implement active semiconductor layers to produce electron current. The semiconductor layers generally absorb incoming light to produce excited charge carriers. In addition to the semiconductor layers, solar cells generally include front and back electrodes. The front electrode provides a destination for electrons excited by exposure to the incident light source. The back electrode or “counter electrode” completes the electrical circuit with the front electrode by providing a destination for the holes produced during the exposure to incident light.

One particular type of solar cell is a dye-sensitized solar cell (DSSC). A dye-sensitized solar cell generally uses an organic dye to absorb incoming light to produce excited electrons. The dye sensitized solar cell generally includes two planar conducting electrodes arranged in a sandwich configuration, at least one of which is substantially transparent. A dye-coated semiconductor film separates the two electrodes. The electrodes may comprise a transparent conducting oxide (TCO) film disposed on a substrate, for example. The semiconductor layer is porous and has a high surface area thereby allowing sufficient dye to be attached as a molecular monolayer on its surface to facilitate efficient light absorption. The remaining intervening space between the electrodes and the pores in the semiconductor film (which acts as a sponge) is filled with an organic electrolyte solution containing an oxidation/reduction couple, such as triiodide/iodide, for example.

One exemplary technique for fabricating a dye-sensitized solar cell is to coat a flexible substrate having a conductive layer (e.g., TCO) disposed thereon with a semiconductor film such as titanium oxide (TiO₂) or zinc oxide (ZnO), for example. As will be appreciated, the substrate having the conductive layer disposed thereon forms a first electrode. The semiconductor film is saturated with a dye and a single layer of dye molecules self-assembles on each of the particles in the semiconductor film, thereby “sensitizing” the film. A liquid electrolyte solution containing triiodide/iodide is introduced into the semiconductor film. The electrolyte fills the pores and openings left in the dye-sensitized semiconductor film. To complete the solar cell a second flexible substrate having a conductive layer disposed thereon to form the second electrode having low overpotential for triiodide reduction is employed to provide a structure having a dye-sensitized semiconductor and electrolyte composite sandwiched between the two electrodes.

One problem associated with solar cells is electrical shorting between electrodes. Shorting between electrodes is of particular concern when implementing flexible substrates. One technique for mitigating electrical shorting between electrodes is to increase the thickness of the active material between the electrodes. However, the thicker the semiconductor film, the greater the distance the electrons and ions may travel to reach an electrode. Although longer light paths may be desirable to facilitate greater light absorption, the current losses due to the increased recombination of the charge carriers, as well as limits to current caused by slow ion diffusion through the electrolyte in the semiconductor pores, make the increased thickness in the semiconductor film disadvantageous since it may produce a less efficient solar cell.

Embodiments of the present invention may address one or more of the problems set forth above.

### BRIEF DESCRIPTION OF THE INVENTION

In accordance with one aspect of the present technique, there is provided a solar cell comprising a first electrode, a hole blocking layer disposed on the first electrode, an active layer disposed on the hole blocking layer an electron blocking layer disposed on the active layer, and a second electrode disposed on the electron blocking layer.

In accordance with another aspect of the present technique, there is provided a solar cell comprising a first electrode, a first hole blocking layer disposed on the first electrode, a first active layer disposed on the first hole blocking layer, a first electron blocking layer disposed on the first active layer, a second electrode disposed on the electron blocking layer, wherein the second electrode comprises a substrate having conductive layers disposed on each the front surface and the back surface of the substrate, a second electron blocking layer disposed on the back surface of the second electrode, a second active layer disposed on the second electron blocking layer, a second hole blocking layer disposed on the second active layer, and a third electrode disposed on the second hole blocking layer.

In accordance with a yet another aspect of the present technique, there is provided a method of forming a solar cell comprising forming an anode component comprising a first electrode, a hole blocking layer disposed on the first electrode and an active layer disposed on the hole blocking layer, forming a cathode component comprising a second electrode and an electron blocking layer disposed on the active layer, and laminating the anode component and the cathode component together.

In accordance with a still another aspect of the present technique, there is provided a method of forming a solar cell comprising forming an anode component comprising a first electrode, a hole blocking layer disposed on the first electrode, an active layer disposed on the hole blocking layer and an electron blocking layer disposed on the active layer, forming a cathode component comprising a second electrode, and laminating the anode component and the cathode component together.

### BRIEF DESCRIPTION OF THE DRAWINGS

Advantages and features of the invention may become apparent upon reading the following detailed description and upon reference to the drawings in which:

FIG. 1 illustrates a cross-sectional view of an exemplary embodiment of a dye-sensitized solar cell having blocking layers in accordance with embodiments of the present invention;

FIG. 2 illustrates a cross-sectional view of a first exemplary embodiment of the active layer of the solar cell of FIG. 1 in accordance with embodiments of the present invention;

FIG. 3 illustrates a cross-sectional view of a second exemplary embodiment of the active layer of the solar cell of FIG. 1 in accordance with embodiments of the present invention;

FIG. 4 illustrates a cross-sectional view of a third exemplary embodiment of the active layer of the solar cell of FIG. 1 in accordance with embodiments of the present invention;

FIG. 5 illustrates a cross-sectional view of a fourth exemplary embodiment of the active layer of the solar cell of FIG. 1 in accordance with embodiments of the present invention;

FIG. 6 illustrates a cross-sectional view of a fifth exemplary embodiment of the active layer of the solar cell of FIG. 1 in accordance with embodiments of the present invention;

FIG. 7 illustrates a cross-sectional view of a sixth exemplary embodiment of the active layer of the solar cell of FIG. 1 in accordance with embodiments of the present invention;

FIG. 8 is a diagrammatic view illustrating a first exemplary technique for fabricating the solar cell of FIG. 1 in accordance with embodiments of the present invention;

FIG. 9 is a diagrammatic view illustrating a second exemplary technique for fabricating the solar cell of FIG. 1 in accordance with embodiments of the present invention; and

FIG. 10 is a diagrammatic view illustrating an exemplary technique for fabricating a parallel tandem solar cell in accordance with further embodiments of the present invention.

### DETAILED DESCRIPTION OF SPECIFIC EMBODIMENTS

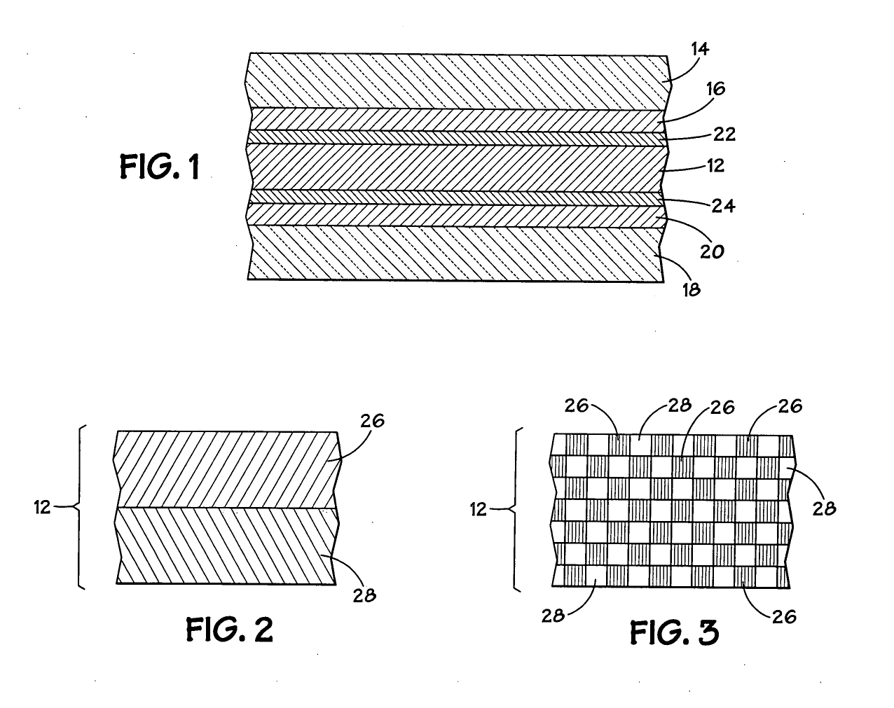

FIG. 1 illustrates an exemplary embodiment of a dye-sensitized solar cell 10, in accordance with embodiments of the present invention. The solar cell 10 may be fabricated by implementing any one of a number of techniques and using a variety of materials, as can be appreciated by those skilled in the art. The solar cell 10 includes an active layer 12 arranged between a first substrate 14 and a second substrate 18. The substrate 14 is transparent to allow impinging light to pass through the substrate 14. As used herein, “transparent” refers to a material allowing a total transmission of at least about 50%, preferably at least about 80% or higher, of visible light (i.e., having a wave length in the range from about 400 nm to about 700 nm).

Further, in accordance with one exemplary embodiment, the substrate 14 is generally thin and flexible, having a thickness in the range of approximately 0.25-50.0 mils, and preferably in the range of approximately 0.5-10.0 mils. As used herein, the term “flexible” generally means being capable of being bent into a shape having a radius of curvature of less than approximately 100 cm. The flexible substrate 14 may be dispensed from a roll, for example. Advantageously, implementing a roll of transparent film for the flexible substrate 14 enables the use of high-volume, low cost, reel-to-reel processing and fabrication of the solar cell 10. The roll of transparent film may have a width of 1 foot, for example, on which a number of solar cells may be fabricated and excised. The substrate 14 may comprise a single layer or may comprise a structure having a plurality of adjacent layers of different materials. The substrate 14 has an index of refraction in the range of approximately 1.05-2.5, and preferably in the range of approximately 1.1-1.6. Further, the substrate 14 generally comprises any flexibly suitable polymeric material. For instance, the substrate 14 may comprise polycarbonates, polyarylates, polyetherimides, polyethersulfones, polyimides, such as Kapton H or Kapton E (made by Dupont) or Upilex (made by UBE Industries, Ltd.), polynorbornenes, such as cyclic-olefins (COC), liquid crystal polymers (LCP), such as polyetheretherketone (PEEK), polyethylene terephthalate (PET), and polyethylene naphtalate (PEN).

The substrate 14 is coated with a transparent conductive layer, such as a transparent conducting oxide (TCO) layer 16. The first substrate 14 and the TCO layer 16 form the front or solar electrode of the solar cell 10. As previously described, the front electrode provides a destination for electrons excited by exposure to the incident light source.

The second substrate 18 also comprises a flexible material. The second substrate 18 may comprise the same material as described above with reference to the substrate 14. The second substrate 18 may or may not be transparent. The second substrate 18 may be coated with a platinized or carbonized TCO layer 20. As will be appreciated, the second substrate 18 and the platinized TCO layer 20 form the back or counter electrode. As will be appreciated, each electrode includes a conductive material. Thus, as described above, each electrode may include a non-conductive substrate having a conductive material (e.g., metal) disposed thereon. Alternatively, the first substrate 14 or second substrate 18 may comprise a flexible metal, such that the substrate 14 or 18 is conductive and forms an electrode without an additional metal layer disposed thereon. Regardless, those skilled in the art will appreciate that at least one of the electrodes is substantially transparent.

The active layer 12 is a composite layer comprising materials configured to convert solar light into electron/hole current. As used herein, “adapted to,” “configured to,” and the like refer to elements that are sized, arranged or manufactured to form a specified structure or to achieve a specified result. The active layer 12 has three basic functions: absorbing light, transporting electrons to the front electrode, and transporting holes to the back electrode. As will be described further with reference to FIGS. 2-7, the active layer 12 may comprise any one of a number of compositions. Generally, the active layer 12 includes an electron transport material (etm) and a hole transport material (htm) which form an active composite layer. In one exemplary embodiment, the active layer 12 comprises a dye-sensitized layer of nanocrystalline titanium dioxide (TiO₂) for electron transport (etm) and an electrolyte material for hole transport (htm). As can be appreciated, the dye used to saturate and sensitize the TiO₂ of the active layer 12 may include group VIII metal complexes of bipyridine carbonoxylic acids, such as Ru(4,4′-dicarbonxy-2,2′-bipyridyl)₂SCN)₂, for instance. Once the TiO₂ is saturated, the dye-coated TiO₂ may be rinsed and cleaned before the electrolyte material is injected into the active layer 12. The electrolyte material is typically an organic solvent. As will be appreciated, various other materials may be employed to provide light absorption, electron transport and hole transport.

In accordance with embodiments of the present invention, the active layer 12 may be disposed at thickness in the range of approximately 5 to 20 microns, for example. As will be appreciated, there are competing reactions to be considered in solar cell design and fabrication. The minimum thickness of the active layer 12 should be sufficient to facilitate efficient light absorption. While the thickness of the active layer 12 should be sufficient to facilitate desired light absorption, to achieve high efficiency solar cell, the cell thickness should be minimized. As will be appreciated, a thinner solar cell 10 provides a shorter charge carrier transport distance which is desirable in solar cells because organic charge transporters have low mobility constants. Further, a thinner solar cell is advantageous in that it leads to low light loss through the electrolyte. As will be appreciated, the absorbance and scattering of the light increases as the thickness of the solar cell increases. However, as previously described thinner solar cells create design challenges and increase the risk of electrical shorting between the electrodes. This is especially true for solar cells implementing flexible substrates. While gaskets may be employed to mitigate the risk of shorting, misalignment or surface roughness of the electrode may still enhance the probability of electrical shorting between electrodes to an undesirable level.

To address these concerns without substantially increasing the thickness of the solar cell 10, the solar cell 10 also employs blocking layers 22 and 24 disposed directly adjacent to the front and back electrodes. More specifically, the blocking layer 22 comprises a hole blocking layer 22 and the blocking layer 24 comprises an electron blocking layer 24. The thickness of the each of the hole blocking layers 22 and 24 is generally in the range of approximately 10 nm to about 1000 nm. The hole blocking layer 22 is configured to block hole transport to the TCO layer 16 of the solar electrode while having little or no effect on the electron transport to the platinized TCO layer 20 or the counter electrode. The hole blocking layer 22 may comprise a dense titanium oxide (TiO₂), for example. As will be appreciated, because of the dense nature of the TiO₂ layer, it will block holes from migrating to the TCO layer 16 of the solar electrode thereby preventing electrons from being taken away from the solar electrode. Other materials suitable for the hole blocking layer 22 may include, but are not limited to, dense oxides of zirconium, hafnium, strontium, zinc, indium, tin, antimony, yttrium, lanthanum, vanadium, niobium, tantalum, chromium, molybdenum, tungsten, and mixtures of such oxides. The material for hole blocking layer 22 should provide appropriate electronic conduction energy level, that is in between that of the TCO and that of the porous semiconductor material. Also it will be appreciated that the terms “electron blocking,” or “hole blocking” refer to relative conductivity, so that the material that is a significantly better electron conductor than it is a hole conductor will be referred to as “hole blocking,” and vice versa. The electron blocking layer 24 is configured to block electron transport to the platinized TCO layer 20 of the counter electrode while having little or no effect on the hole transport. The electron blocking layer 24 may comprise a porous silicon dioxide (SiO₂), for example. Other materials suitable for the electron blocking layer 24 may include, but are not limited to, porous oxides of aluminum, boron, phosphorus, and mixtures of such oxides. Also, it may include organic polymers such as polymethylmethacrylate, polyethylene, polystyrene and polypropylene, for example. Electron blocking materials in the form of beads (having a bead size larger than the TiO2 pore size, but preferably not exceeding several μm) can be also dispersed in electrolyte, and thus introduced into the device with the electrolyte. Advantageously, by employing the blocking layers 22 and 24 in the solar cell 10 in accordance with embodiments of the present invention, the undesirable back reactions (i.e., htm with the solar electrode, and etm with the counter electrode), can be eliminated. Further, the two blocking layers 22 and 24 advantageously prevent shorting between the solar electrode and the counter electrode.

Turning now to FIGS. 2-7, specific exemplary embodiments of the active layer 12 having a hole transport material (htm) 26 and an electron transport material (etm) 28 are illustrated. Specifically, FIG. 2 illustrates an embodiment of the active layer 12 wherein the htm 26 and the etm 28 are two distinct and separate layers disposed independently of one another. In this embodiment, the htm 26 and etm 28 may comprise solid form materials. The htm 26 and etm 28 may be disposed by chemical vapor deposition (CVD), for example. Alternatively, the htm 26 and etm 28 may be disposed via plasma-enhanced chemical-vapor deposition (PECVD), radio-frequency plasma-enhanced chemical-vapor deposition (RFPECVD), expanding thermal-plasma chemical-vapor deposition (ETPCVD), reactive sputtering, electron-cyclodrawn-residence plasma-enhanced chemical-vapor deposition (ECRPECVD), inductively coupled plasma-enhanced chemical-vapor deposition (ICPECVD), sputter deposition, evaporation, atomic layer deposition (ALD), or combinations thereof. Alternatively, one of the charge transport materials, etm 28 or htm 26, can be in two distinct phases. For examples, the htm 26 can be in the solid phase while the etm 28 is in the liquid phase. More specifically the solid htm 26 may comprise TiO2, and the liquid etm 28 may comprise the redox electrolyte. The solid phase can be made using the above deposition methods. Alternatively it can be disposed by various printing or coating techniques. The liquid phase can be disposed made by vacuum-filling or injection.

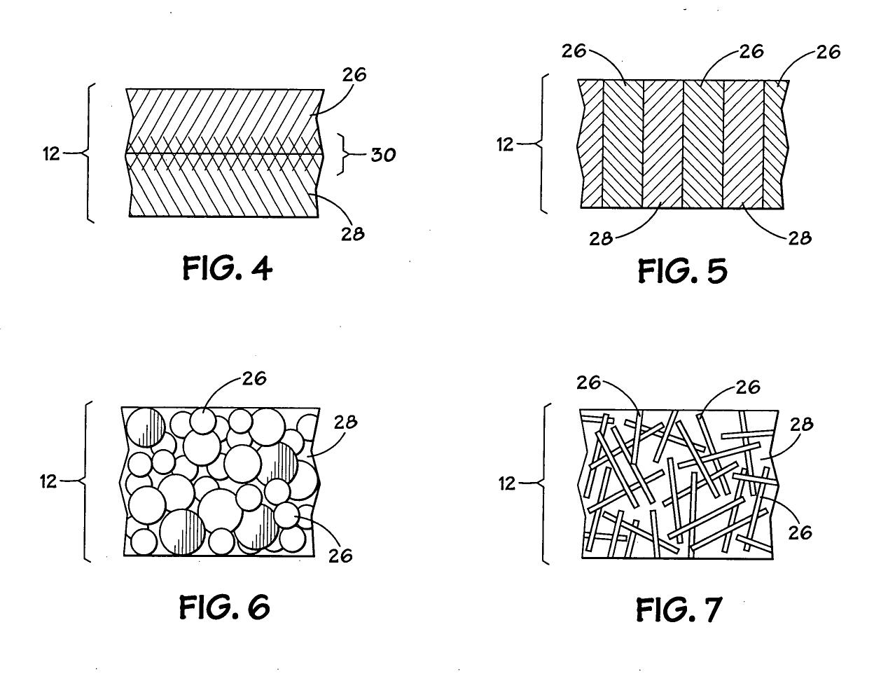

FIG. 3 illustrates an active layer 12 wherein the htm 26 and the etm 28 are two different phases. In the illustrated embodiment, the etm 28 is a porous solid and the htm 26 is a liquid phase injected into the etm 28. FIG. 4 illustrates an active layer 12 wherein the htm 26 and the etm 28 are graded such that there is an overlapping graded region 30. In accordance with this embodiment, the grading of the htm 26 with the etm 28 may be uniform, as illustrated. Alternatively, the graded region 30 may be non-uniform. This can be done by changing etm or/and htm deposition conditions such as material composition and deposition rate. FIG. 5 illustrates an active layer 12 wherein the htm 26 and the etm 28 are interdigitated. For instance, the htm 26 may be disposed initially via CVD, for example. Next, cavities may be formed through the htm 26 via selective etching or laser ablation, for example. Finally, the etm 28 may be disposed in the cavities to form the active layer 12 illustrated in FIG. 5.

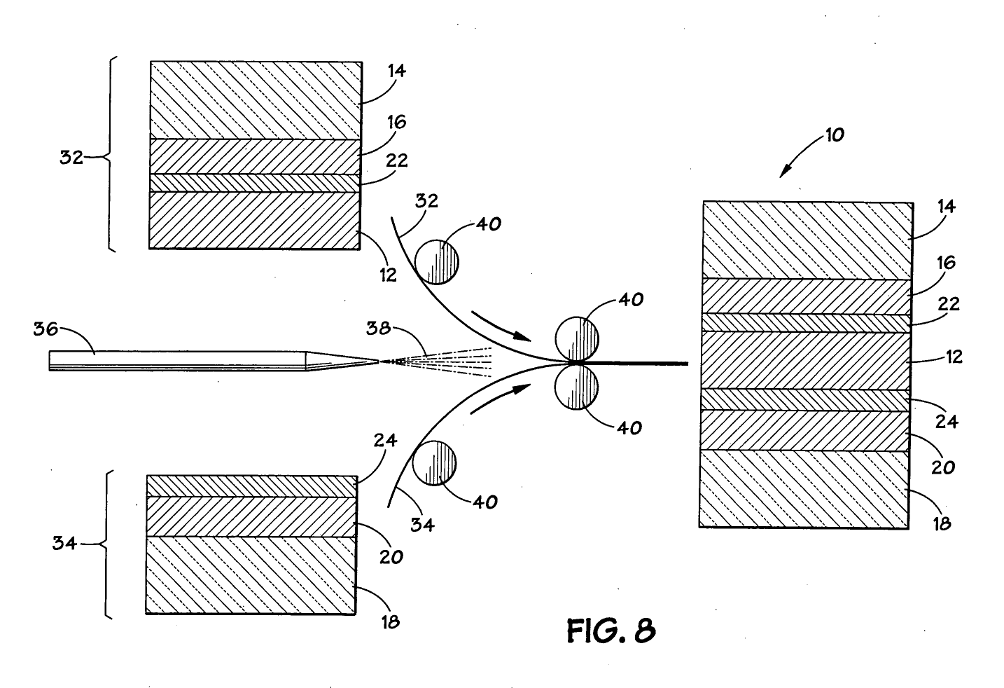

FIG. 6 illustrates an active layer 12 having a combination of the configuration of FIGS. 3 and 4. Specifically, the etm 28 includes a number of particles, such as TiO₂, which are arranged in a direction perpendicular to the surface of the electrode. The particles of the etm 28 vary in size and shape. The htm 26 of FIG. 6 is a liquid phase material, such as electrolyte, which may be injected into the porous etm 28. Advantageously, the active layer 12 of FIG. 6 provides a mechanism for reducing resistance loss by getting more photocurrent near the electric contacting layer and better overall light management. The active layer 12 illustrated in FIG. 7 includes an etm 28 in a fiber form and with a disordered orientation. The fiber form etm 28 is surrounded by a liquid phase htm 26. Alternatively, the fiber form etm 28 may have an ordered orientation extending perpendicular to the surface of the electrode.

As will be appreciated, various other embodiments of the active layer 12 incorporating various configurations of the htm 26 and etm 28 may be employed in the solar cell 10, in accordance with embodiments of the present invention.

Referring now to FIG. 8, an exemplary technique for fabricating the solar cell 10 in accordance with embodiments of the present invention, is illustrated. In the illustrated embodiment, the anode component 32 and the cathode component 34 of the solar cell 10 are fabricated independently. Specifically, the anode component 32 includes the first substrate 14, the TCO layer 16, the hole blocking layer 22 and the active layer 12. In accordance with the present embodiment, the active layer 12 comprises a dye-sensitized porous TiO₂ material which is disposed directly on the hole blocking layer 22. The cathode component 34 includes the substrate 18, the platinized TCO layer 20 and the electron blocking layer 24, such as SiO₂. As will be appreciated, the anode component 32 and the cathode component 34 are flexible and may be laminated together using a roll-to-roll process. In the present exemplary embodiment, the anode component 32 and the cathode component 34 guided by rollers 40 while an electrolyte injector 36 injects electrolyte 38 into the porous TiO₂ of the active layer 12. Once the anode component 32 and the cathode component 34 are laminated together, the solar cell 10 fabricated in accordance with embodiments of the present invention may be achieved.

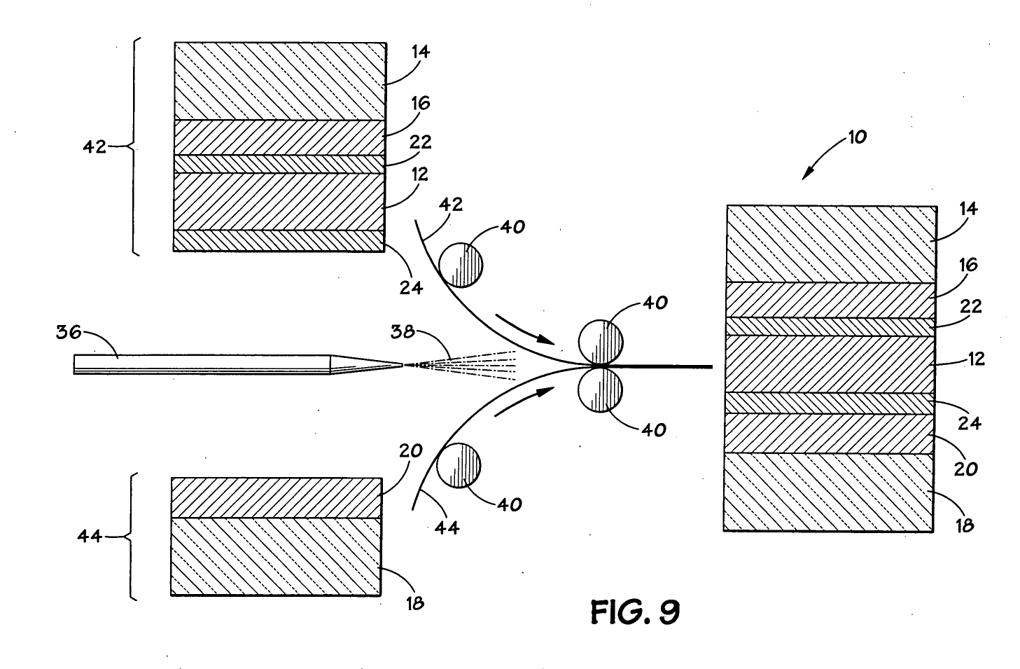

Turning now to FIG. 9, an alternate method of fabricating the solar cell 10 is illustrated. In the embodiment illustrated in FIG. 9, the anode component 42 includes the substrate 14, the TCO layer 16, the hole blocking layer 22, such as dense TiO₂, the active layer 12, such as porous TiO₂, and the electron blocking layer 24, such as SiO₂. The cathode component 44 includes the substrate 18 and the platinized TCO layer 20. As will be appreciated, the embodiment illustrated in FIG. 9 illustrates the electron blocking layer 24 being fabricated directly on the active layer 12 of the anode component 42, rather than on the platinized TCO layer 20 of the cathode component 44.

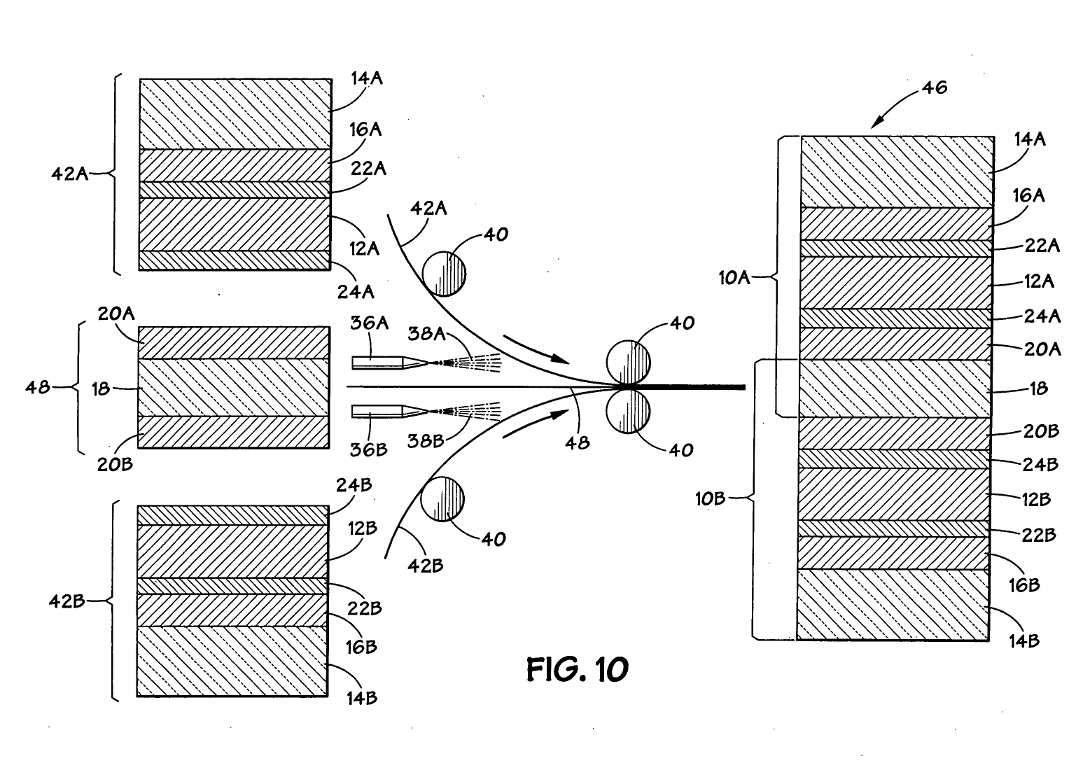

FIG. 10 illustrates a parallel tandem solar cell 46 which may be fabricated in accordance with embodiments of the present technique. Essentially, the parallel tandem solar cell 46 includes two solar cells 10A and 10B which share a common substrate 18. In the present exemplary embodiment, anode components 42A and 42B are fabricated independently. The front anode component 42A includes substrate 14A, TCO layer 16A, hole blocking layer 22A, active layer 12A and electron blocking layer 24A. Similarly, the back anode component 42B includes the substrate 14B, TCO layer 16B, hole blocking layer 22B, active layer 12B and electron blocking layer 24B. The cathode component 48 includes a substrate 18 having platinized TCO layers 20A and 20B disposed on both sides. During the lamination process, the rollers 40 will guide each of the front anode component 42A, the back anode component 42B and the cathode component 48 through the rollers 40 while electrolyte injectors 36A and 36B inject electrolyte 38A and 38A into the active layers 12A and 12B, respectively.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims. Specifically, it will be understood that “anode component” and “cathode component” and the various exemplary embodiments of fabricating those components are provided by way of example. Those skilled in the art will appreciate that the fabrication techniques described herein may be modified such that layers are disposed on one or the other of the components before lamination. For example, the active layer(s) may be disposed on one or both of the anode component and the cathode component in accordance with the spirit and scope of the present invention.

What is claimed is:

1. A solar cell comprising:
a first electrode;
a hole blocking layer disposed on the first electrode;
an active layer disposed on the hole blocking layer;
an electron blocking layer disposed on the active layer; and
a second electrode disposed on the electron blocking layer.

2. The solar cell, as set forth in claim 1, wherein each of the first and second electrodes comprise a flexible substrate having a conductive layer disposed thereon.

3. The solar cell, as set forth in claim 1, wherein the hole blocking layer comprises a dense titanium oxide (TiO₂).

4. The solar cell, as set forth in claim 1, wherein the electron blocking layer comprises a porous silicon dioxide (SiO2).

5. The solar cell, as set forth in claim 1, wherein the active layer comprises a composite layer comprising a hole transport material and an electron transport material.

6. The solar cell, as set forth in claim 5, wherein the hole transport material and the electron material comprise separate layers.

7. The solar cell, as set forth in claim 5, wherein the hole transport material and the electron material comprise different phases.

8. The solar cell, as set forth in claim 5, wherein the active layer comprises an overlapping graded region comprising a portion of the hole transport material and a portion of the electron material.

9. The solar cell, as set forth in claim 5, wherein the hole transport material and the electron material are interdigitated vertically with respect to the first and second electrodes.

10. The solar cell, as set forth in claim 5, wherein the electron material comprises one of particles or rods.

11. A solar cell comprising:
a first electrode;
a first hole blocking layer disposed on the first electrode;
a first active layer disposed on the first hole blocking layer;
a first electron blocking layer disposed on the first active layer;
a second electrode disposed on the electron blocking layer, wherein the second electrode comprises a substrate having conductive layers disposed on each the front surface and the back surface of the substrate;
a second electron blocking layer disposed on the back surface of the second electrode;
a second active layer disposed on the second electron blocking layer;
a second hole blocking layer disposed on the second active layer; and
a third electrode disposed on the second hole blocking layer.

12. The solar cell, as set forth in claim 11, wherein each of the first, second and third electrodes comprise a flexible substrate having at least one conductive layer disposed thereon.

13. The solar cell, as set forth in claim 11, wherein each of the first and second hole blocking layer comprises a dense titanium oxide (TiO₂).

14. The solar cell, as set forth in claim 11, wherein each of the first and second electron blocking layer comprises a porous silicon dioxide (SiO2).

15. A method of forming a solar cell comprising:
forming an anode component comprising a first electrode, a hole blocking layer disposed on the first electrode and an active layer disposed on the hole blocking layer;
forming a cathode component comprising a second electrode and an electron blocking layer disposed on the active layer; and
laminating the anode component and the cathode component together.

16. The method, as set forth in claim 15, wherein forming the anode component comprises:
providing a flexible substrate;
disposing a conductive layer on the flexible substrate to form the first electrode;
disposing the hole blocking layer on the conductive layer; and
disposing the active layer on the hole blocking layer.

17. The method, as set forth in claim 16, wherein disposing the hole blocking layer comprises disposing a dense titanium oxide (TiO₂) on the conductive layer.

18. The method, as set forth in claim 15, wherein forming the cathode component comprises:
providing a flexible substrate;
disposing a conductive layer on the flexible substrate to form the second electrode; and
disposing the electron blocking layer on the conductive layer.

19. The method, as set forth in claim 18, wherein disposing the electron blocking layer comprises disposing a porous silicon dioxide (SiO2) on the conductive layer.

20. The method, as set forth in claim 15, wherein laminating the anode component and the cathode component together comprises injecting an electrolyte into the active layer during lamination.

21. The method, as set forth in claim 15, wherein laminating the anode component and the cathode component together is performed using roll-to-roll processing.

22. A method of forming a solar cell comprising:
forming an anode component comprising a first electrode, a hole blocking layer disposed on the first electrode, an active layer disposed on the hole blocking layer and an electron blocking layer disposed on the active layer;
forming a cathode component comprising a second electrode; and
laminating the anode component and the cathode component together.

23. The method, as set forth in claim 22, wherein forming the anode component comprises:
providing a flexible substrate;
disposing a conductive layer on the flexible substrate to form the first electrode;
disposing the hole blocking layer on the conductive layer;
disposing the active layer on the hole blocking layer; and
disposing the electron blocking layer on the active layer.

24. The method, as set forth in claim 23, wherein disposing the hole blocking layer comprises disposing a dense titanium oxide (TiO₂) on the conductive layer.

25. The method, as set forth in claim 23, wherein disposing the electron blocking layer comprises disposing a porous silicon dioxide (SiO2) on the conductive layer.

26. The method, as set forth in claim 22, wherein forming the cathode component comprises:
providing a flexible substrate;
disposing a conductive layer on the flexible.

27. The method, as set forth in claim 22, wherein laminating the anode component and the cathode component together comprises injecting an electrolyte into the active layer and the electron blocking layer during lamination.

28. The method, as set forth in claim 22, wherein laminating the anode component and the cathode component together is performed using roll-to-roll processing.

29. A method of forming a solar cell comprising:
forming an anode component comprising a first electrode;
forming a cathode component comprising a second electrode, an electron blocking layer disposed on the second electrode and a first partial active layer disposed on the electron blocking layer; and
injecting a second partial active layer and a hole blocking layer between the anode component and cathode component while laminating the anode component and cathode component together.

30. The method, as set forth in claim 29, wherein the first partial active layer comprises a mesoporous film of titanium oxide (TiO₂) nanoparticles and the second partial active layer comprises a redox liquid electrolyte.

31. The method, as set forth in claim 30, wherein the hole blocking layer comprises insulating particles having a size greater than a pour size of the mesoprous film.
